(19) United States
(12) Patent Application Publication
(10) Pub. No.: US 2026/0362644 A1
(43) Pub. Date: Nov. 12, 2026

(54) ELECTRIC VEHICLE THERMAL MANAGEMENT SYSTEM

(71) Applicant: QION, INC., Boston, MA (US)

(72) Inventor: Ludovico Finotto, Panama City (PA)

(21) Appl. No.: 19/486,704

(22) PCT Filed: May 23, 2024
(86) PCT No.: PCT/US2024/030692

§ 371 Date: Nov. 21, 2025

Related U.S. Application Data
(60) Provisional application No. 63/505,108, filed on May 31, 2023.

(51) Int. Cl. H05K 7/20; B60L 53/18; B60L 53/302

(52) U.S. Cl. CPC H05K 7/20281; B60L 53/18; B60L 53/302; H05K 7/20272

(57) ABSTRACT

Provided are embodiments for a thermal management system and methods. The embodiments can include a pump configured to send coolant to a charging device through a first cooling tube and a second cooling tube, wherein the first cooling tube and the second cooling tube respectively enclose a first power cable and a second power cable connected to the charging device to provide the coolant over the first power cable and the second power cable. The embodiments can further include a heat exchanger that is configured to receive the coolant from the charging device from a first return tube and a second return tube, and a controller that is configured to send a control signal to at least the pump to control an operation of the pump to control a flow of coolant to the charging device.

### CROSS-REFERENCE TO RELATED APPLICATION

This application claims priority to U.S. Provisional Application No. 63/505,108, filed May 31, 2023, the entire contents of which are incorporated herein by reference.

### BACKGROUND

The present invention generally relates to electric charging technology, and more specifically, to a thermal management system for fast-charging of electric vehicles.

With the proliferation of electrical vehicles (EV), owners' desires for fast charging capabilities have increased. Given the limited availability of charging stations and even fewer fast charging stations, the competition against the internal combustion engine vehicle market continues. EV owners often compare the ability to avoid volatile gas prices and gas stations with the convenience of charging their EVs at home or work as a benefit. However, when EV owners travel long distances they may be faced with limited availability of chargers, either due to the location of the chargers or the increased demand for the few available chargers. Coupling these limitations with the fact that EV charging times tend to exceed the average time to fill up a gasoline-powered vehicle, many drivers will steer shy of the EV market until these challenges are addressed or improved. Therefore, there may be a need for a thermal management system to enable reliable and efficient fast-charging technology to permit fast-charging capabilities to meet customer demand.

### SUMMARY

Embodiments of the present invention are directed to a thermal management system. A non-limiting example of the system can include a pump configured to send coolant to a charging device through a first cooling tube and a second cooling tube, wherein the first cooling tube and the second cooling tube respectively enclose a first power cable and a second power cable connected to the charging device to provide the coolant over the first power cable and the second power cable; a heat exchanger configured to receive the coolant from the charging device from a first return tube and a second return tube; and a controller configured to send a control signal to at least the pump to control an operation of the pump to control a flow of coolant to the charging device.

Embodiments of the present invention are directed to a dual thermal management system. A non-limiting example of the system includes a first thermal management system coupled to a charging device, wherein the first thermal management system includes a first pump configured to send coolant to the charging device through a first cooling tube, wherein the first cooling tube encloses a first power cable connected to the charging device to provide the coolant over the first power cable, and a first heat exchanger configured to receive the coolant from the charging device from a first return tube. The second thermal management system is coupled to the charging device, wherein the second thermal management system includes a second pump configured to send coolant to the charging device through a second cooling tube, wherein the second cooling tube encloses a second power cable connected to the charging device to provide the coolant over the second power cable, and a second heat exchanger configured to receive the coolant from the charging device from a second return tube, and a controller operably coupled to the first thermal management system and the second thermal management system to control the flow coolant.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 depicts a conventional cooling system in accordance with one or more embodiments of the invention;

FIG. 2 depicts a block diagram of a thermal management system in accordance with one or more embodiments of the invention;

FIG. 3 depicts a block diagram of a cooling system of a thermal management system in accordance with one or more embodiments of the invention;

FIG. 4 depicts a controller of a thermal management system in accordance with one or more embodiments of the invention;

FIG. 5 depicts a block diagram of a computing device coupled to a thermal management system in accordance with one or more embodiments of the invention;

FIGS. 6A and 6B depict block diagrams of arrangements for the thermal management system in accordance with one or more embodiments of the invention; and

FIG. 7 depicts a flowchart of a method for operating the thermal management system in accordance with one or more embodiments of the invention.

The diagrams depicted herein are illustrative. There can be many variations to the diagram or the operations described therein without departing from the spirit of the invention.

For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the disclosed embodiments, the various elements illustrated in the figures are provided with two or three-digit reference numbers. With minor exceptions, the leftmost digit(s) of each reference number correspond to the figure in which its element is first illustrated.

### DETAILED DESCRIPTION

Various embodiments of the invention are described herein with reference to the related drawings. Alternative embodiments of the invention can be devised without departing 3 from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect.

Accordingly, a coupling of entities can refer to either a direct or an indirect coupling, and a positional relationship between entities can be a direct or indirect positional relationship.

Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.”

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

Turning now to an overview of technologies that are more specifically relevant to aspects of the invention, a variety of different types of charging stations and charging devices can be used for charging electric vehicles. For example, some charging technologies include alternating current (AC) chargers and others include direct current (DC) chargers. A third category, known as combined charging systems (CCS) uses a combination of AC and DC charging technologies. For CCS, the AC charging connections are arranged in the top portion of the charging plug, while the DC charging connections are arranged in the bottom portion of the plug. During the charging sequence, the current flowing through the power cables of charging stations generate heat. This issue is exacerbated during a fast charging sequence because more power and higher current are delivered to the load. Other types of charging connectors exist, such as J1772 (type 1) and CCS (type 1). The types of charging connectors available may be based on geographic location. For example, the charging types that are available in North America are generally the J1772 and CCS type 1 connectors, while other types may be used in the Asian and European markets. Other charging types can include Megawatt charging system (MCS) and GB/T charging standards.

The charging components, such as the charging plug, the power cables, etc., have specific current and temperature constraints that must be adhered to in order to prevent damage and failure of the system. During the charging cycle, if the generated heat is not removed sufficiently enough to stay within the operating specification of the components, the generated heat can damage the charging components and lead to failure.

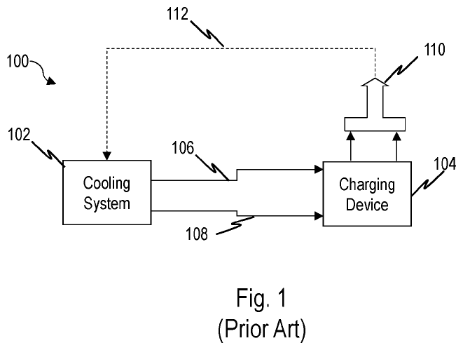

Additionally, existing thermal management systems do not provide sufficient heat removal to increase the current carrying capacity of the charging systems to increase the power delivered to the EV and reduce charging times. A conventional system, such as system 100 of FIG. 1, uses a single return cooling line to extract heat from charging device 104. The system 100 also includes a cooling system 102 that is coupled to the charging device 104. The cooling system 102 delivers coolant to the charging device 104 over cooling tubes 106, 108. After the coolant from the cooling tubes 106, 108 absorbs the heat from the charging device 104, the coolant from each cooling tube 106, 108 is combined at a T-valve 110 and a single coolant return line 112 is provided to the cooling system 102.

As EV chargers are operated during the charging cycle, the current flow through the power cables causes the cables and charging device to generate excess heat. This generated heat, if not managed, can cause the charging device to break down and fail resulting in unreliable charging systems. To address this issue, existing EV charging systems limit the power, (e.g., the amount of current) that is provided to charge the EV, which in turn results in longer charging times. This restriction increases the charging time for the EV leading to an inconvenience to EV customers.

In addition to the heat generated during the operation of the EV chargers, existing thermal management systems are deficient in removing heat from the charging device and cables. For example, existing systems utilize a single extraction cooling mechanism, which limits the capacity/efficiency of the coolant flow such as that shown in FIG. 1. The system 100 depicts an existing cooling which couples the cooling tubes into a single coolant return line 112, via a T-valve 110 which further restricts coolant flow by forming a bottleneck. The amount of heat generated during the charging cycle is proportional to the amount of current carried in the power cables. The implementation of fast charging systems, such as those systems that 50 kW and higher, has been limited due to the ability to manage the heat generated by the high current flow from the power source through the cables to the charging device/interface (e.g., charging plug) that connects to the electric vehicle. These limitations can deter drivers from entering the EV market.

What is needed is a technique and mechanism for implementing a dynamic thermal management system to remove excess heat from the charging device. To enable fast-charging capabilities, the amount of power and current carried by the charging device must be increased resulting in higher operating temperatures. One or more embodiments of the invention include a dual extraction cooling technique to improve heat removal during a fast-charging cycle.

Turning now to an overview of the aspects of the invention, one or more embodiments of the invention address the above-described shortcomings of the prior art by providing a dual extraction thermal management system for electrical charging stations. The thermal management system includes using dual coolant return lines from the charging device to the cooling system to increase the cooling capacity of the system. The dual coolant return lines can efficiently remove heat from the EV fast charging system. In one or more embodiments of the invention, a dual cooling tube arrangement encloses the respective charging cables and because a pair of cooling tubes are used, a “straight” valve can be used which does not restrict the flow of coolant flow in the thermal management systems. As previously discussed with reference to FIG. 1, conventional cooling systems include a “T-valve” to couple the separate cooling lines into a single coolant return line. By replacing the single return line with a pair of coolant return lines, the heat-removing capacity of the system will be increased.

The above-described aspects of the invention address the shortcomings of the prior art by implementing a dual extraction thermal management system for an EV fast charging that can dynamically control a cooling system to safely operate the EV fast charging device and/or charging station.

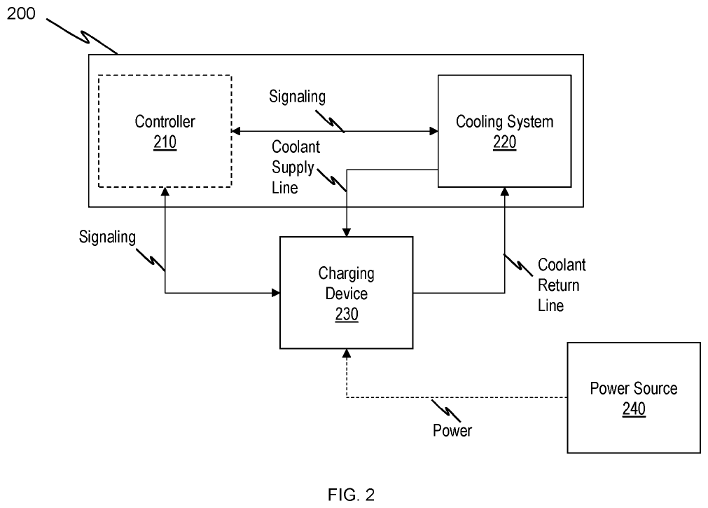

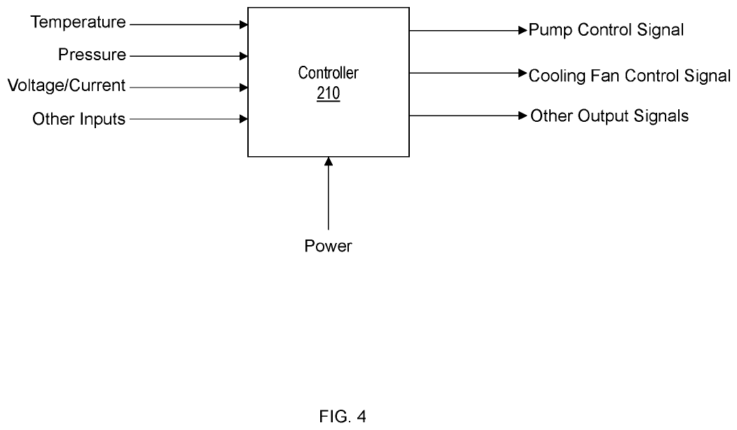

Turning now to a more detailed description of aspects of the present invention, FIG. 2 depicts a block diagram of a thermal management system 200 (referred to as “TMS 200”) according to one or more embodiments. The TMS 200 includes a controller 210 that is operably coupled to the cooling system 220. The controller 210 is configured to receive various inputs (e.g., electrical signal inputs) from the cooling system 220 and the charging device 230. The charging device 230 can include various EV connector types such as but not limited type 1 and type 2 CCS connections. The controller 210 can be further configured to transmit control signals or power signals to various components in the TMS 200 to control the removal of heat generated from the current flow through the cables of the charging device 230 and power source 240 based on the signals received from the TMS 200 and the charging device 230. Additionally, the controller 210 can be configured to dynamically increase and/or decrease the cooling of the cables based on sensing various conditions (e.g., temperature, pressure, etc.) and transmitting control signals to one or more components of the cooling system 220. The sensed conditions may be compared to a configurable threshold stored in a memory of the controller 210. Although the controller 210 is shown as being located internal to the TMS 200, in other embodiments, the controller 210 can be located external to the TMS 200 and can be operably coupled to the various components of the cooling system 220 and charging device 230 over a connection. Details of the controller 210 are further discussed below with reference to FIG. 4.

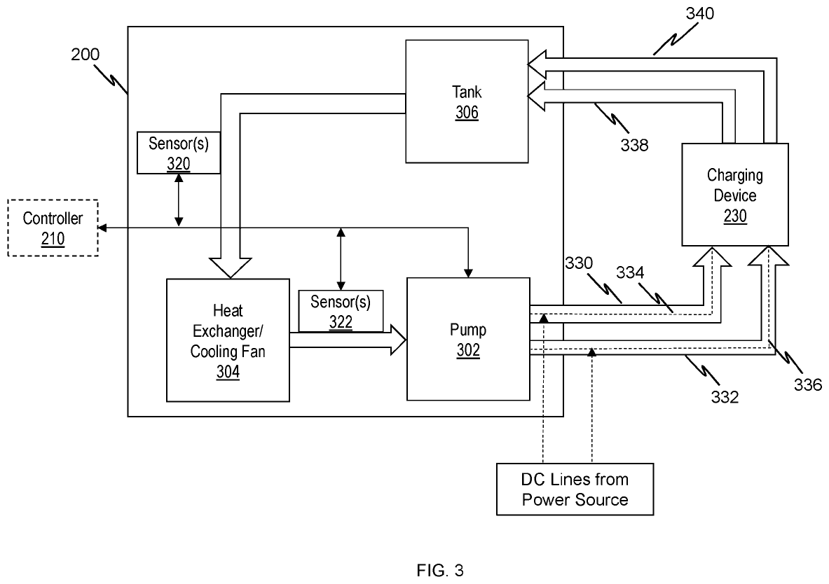

FIG. 2 also illustrates the cooling system 220 providing coolant to the charging device 230 through the coolant supply line and removing the excess heat absorbed by the coolant from the coolant return line. Although the coolant supply and return lines are represented by a single line, it should be understood that each supply line and coolant line represents two or more supply lines and return lines. Additional details of the cooling system 220 are further discussed below with reference to FIG. 3. The plurality of lines increases the capacity for cooling according to one or more embodiments of the invention.

Referring back to FIG. 1, conventional systems use a single cooling tube coupling the charging device 104 to the cooling system 102 to implement thermal management. However, this technique leads to several inefficiencies that have been addressed by one or more embodiments of the invention. The cooling tubes of the conventional systems are positioned adjacent to the power cables, where the power cables generate heat during operation. In this arrangement, the location of the power cables inhibits the removal of heat from the cooling tubes which limits its ability to remove heat. Thus, resulting in limiting the power that can be supplied by the EV charging system. By placing the tubes away from the heat-generating power cables, the cooling tubes are less likely to absorb heat from the charging cables that are within proximity.

FIG. 3 depicts a block diagram of the cooling system 220 implemented in the TMS 200 in accordance with one or more embodiments of the invention. The cooling system 220 includes a plurality of components to facilitate the removal of heat generated from the power cables during the charging cycle. In a non-limiting example, the cooling system 220 includes a pump 302, a heat exchanger 304, and an expansion tank 306. The pump 302 can be electrically controlled, by a controller 210, to modify the pressure in the TMS 200 to force the coolant to flow through the TMS 200. The pump 302 can be operated at different speeds to control the rate of coolant flow through the system based on a signal received from the controller 210. In some embodiments, the pump 302 may be operated in an ON/OFF mode where the pump 302 is operated at a constant speed when powered ON to consistently force the coolant to flow throughout the TMS 200. The cooling tubes 330, 332 carrying the coolant are coupled to the power cables 334, 336 carrying power to the charging device 230 to remove the heat generated from the power cables 334, 336 during the charging cycle. In this non-limiting example, each power cable, the DC+ and the DC−, is enclosed in its respective cooling tube 330, 332 which increases the rate at which heat is removed from the TMS 200. As shown in FIG. 3, after the coolant absorbs the heat from the power cables, it is transferred back to the TMS 200 to continuously remove the heat from the power cables 334, 336. A first return tube is coupled to the DC+ power cable and a second return tube is coupled to the DC− power cable to return the coolant that has absorbed the heat to the expansion tank 306. The dual extraction technique according to embodiments of the invention, utilizes respective coolant return lines 338, 340 from the charging device 230 which increases the coolant flow in the TMS 200. Because each DC power cable has its respective coolant return line, there is no need for a T-valve 110, such as that used in the conventional system of FIG. 1, which restricts coolant flow.

The expansion tank 306 can be positioned between the heat exchanger 304 and the charging device 230 to manage increased pressure due resulting from the coolant absorbing heat in the system. Once the coolant leaves the tank 306 it enters the heat exchanger 304. In a non-limiting example, the heat exchanger 304 can be a radiator having several coils to increase the surface area to allow the heat from the coolant to escape. To facilitate increased cooling, some embodiments may include a cooling fan to further remove additional heat from the heat exchanger 304. After the heat is removed from the coolant, it enters the pump 302 and the coolant is pumped to the charging device 230 to continue to remove the heat from the system.

The controller 210 is operably coupled to the components of the cooling system 220. The solid arrows represent the connections between the controller 210 and each of the components such as the pump 302, cooling fan 308, and sensors 320, 322. The sensors 320, 322 can include but are not limited to temperature sensors and pressure sensors. It can be appreciated that other types of sensors can be incorporated into the TMS 200. In one or more embodiments of the invention, the sensors 320, 322 can be positioned at various locations in the TMS 200 to monitor the performance and conditions of the coolant. For example, the sensors 320 can be placed at the inlet of the heat exchanger 304 to measure the temperature and pressure prior to cooling. Additional sensors 322 may be positioned at the output of the heat exchanger 304 and/or cooling fan 308 to measure the temperature and pressure after the coolant has been cooled. The data from the sensors 320, 322 can be provided to the controller 210. The controller 210 can use the data to determine whether to maintain the current operation of the cooling system 220, or increase/decrease the coolant flow by modifying the speed of the pump 302. Additionally, the controller 20 can use the data to maintain the operation of the cooling fan 308, or increase/decrease the speed of the cooling fan 308. It can be appreciated that various threshold values can be set for the temperature, pressure, etc. and the controller 210 will provide control signals to the TMS to maintain the configured thresholds. Additional details of the controller 210 are further discussed with reference to FIG. 4 below.

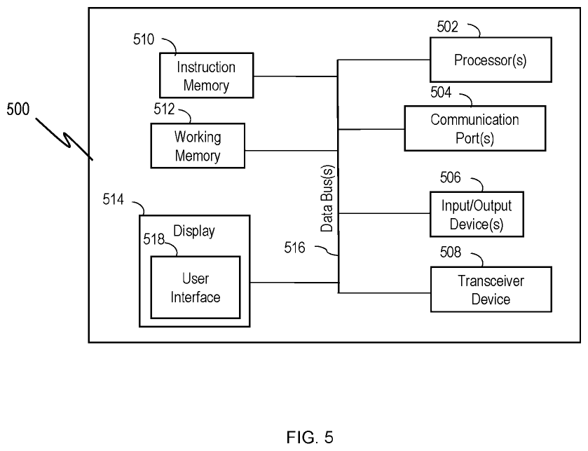

Now referring to FIG. 4, additional details of the controller 210 of TMS 200 are shown. The controller 210 can include a processor and memory such as that shown and described with reference to FIG. 5. In one or more embodiments, the controller 210 can be configured to receive and process a plurality of input signals. In a non-limiting example, the controller 210 can be configured to receive sensor input signals such as that from a temperature sensor and/or pressure sensors that are operably coupled to the TMS 200. The sensors 320, 322 can be placed at the input to the heat exchanger 304 to measure the temperature of the coolant before entering the cooling system. Also, a subsequent temperature sensor can be placed at the output of the heat exchanger 304 to measure the temperature of the coolant exiting the heat exchanger. Similarly, pressure sensors can be placed at the input and output of the heat exchanger. The controller 210 can be further configured to receive a signal from the charging device 230 and/or charging station to detect the operation of the charging sequence. It can be appreciated that the controller 210 can be configured to receive and process “other inputs” (input signals) and is not intended to be limited by the examples discussed herein. For example, the “other inputs” can include receiving input signals from a charger controller (not shown) that is in electrical communication with the controller 210, where the charger controller is configured to control the operation of the charging device 230. Non-limiting examples of “other inputs” received from the charger controller can include but are not limited to current readings, voltage readings, etc. measured at the charging device 230 or charging system.

The controller 210 can be configured to transmit a plurality of output signals both internal to and external to the TMS 200. In one or more embodiments of the invention, the controller 210 can be configured to control the operation of the TMS 200 based at least part on the one or more received input signals such as but not limited to the temperature sensor input, the pressure sensor input, and/or power signal. For example, the controller 210 can determine whether a threshold condition (e.g., threshold temperature, threshold pressure, etc.) has been exceeded. If so, the controller 210 can be configured to provide a control signal to the pump 302 to increase the coolant flow through the TMS 200. Also, the controller 210 can be configured to provide a control signal to the cooling fan 308 to increase its speed to remove the heat from the coolant flowing through the heat exchanger 304. It can be appreciated that the pump 302 can be operated in a plurality of modes based on the sensor input signals received at the controller 210. Similarly, the cooling fan 308 can be operated in a plurality of modes or simply in an ON/OFF mode.

The controller 210 can be configured to transmit “other output signals” and is not intended to be limited by the examples discussed herein. In a non-limiting example, the controller 210 can transmit signals to a display that is operably coupled to the controller 210 which may display the status of one or more elements of the TMS 200. The status information can include but is not limited to temperature information, pressure information, operation information (e.g., charging cycle ON/OFF), cooling fan ON/OFF status, pump ON/OFF status, etc.

FIG. 5 is a block diagram of an example computing device 500 in accordance with some embodiments of the invention. The computing device 500 can be employed by a disclosed system or used to execute a disclosed method of the present disclosure. Computing device 500, such as the controller 210 of the TMS 200 shown in FIG. 2, can implement, for example, one or more of the functions described herein. For example, the functions can include controlling the thermal management and generation of control signals in the TMS 200. It should be understood, however, that other computing device configurations are possible.

Computing device 500 can include one or more processors 502, one or more communication port(s) 504, one or more input/output devices 506, a transceiver device 508, instruction memory 510, working memory 512, and optionally a display 514, all operatively coupled to one or more data buses 516. Data buses 516 allow for communication among the various devices, processor(s) 502, instruction memory 510, working memory 512, communication port(s) 504, and/or display 514. Data buses 516 can include wired, or wireless, communication channels. Data buses 516 are connected to one or more devices.

Processor(s) 502 can include one or more distinct processors, each having one or more cores. Each of the distinct processors 502 can have the same or different structures.

Processor(s) 502 can include one or more central processing units (CPUs), one or more graphics processing units (GPUs), application-specific integrated circuits (ASICs), digital signal processors (DSPs), and the like.

Processor(s) 502 can be configured to perform a certain function or operation by executing code, stored on instruction memory 510, embodying the function or operation of the thermal management system TMS 200 illustrated in FIG. 2. For example, processor(s) 502 can be configured to perform one or more of any function, method, or operation disclosed herein.

Communication port(s) 504 can include, for example, a serial port such as a universal asynchronous receiver/transmitter (UART) connection, a Universal Serial Bus (USB) connection, or any other suitable communication port or connection. In some examples, communication port(s) 504 allows for the programming of executable instructions in instruction memory 510. In some examples, communication port(s) 504 allow for the transfer, such as uploading or downloading, of data.

Input/output devices 506 can include any suitable device that allows for data input or output. For example, input/output devices 506 can include one or more of a keyboard, a touchpad, a mouse, a stylus, a touchscreen, a physical button, a speaker, a microphone, or any other suitable input or output device.

Transceiver device 508 can allow for communication with a network, such as a Wi-Fi network, an Ethernet network, a cellular network, or any other suitable communication network. For example, if operating in a cellular network, transceiver device 508 is configured to allow communications with the cellular network. Processor(s) 502 is operable to receive data from, or send data to, a network via transceiver device 508.

Instruction memory 510 can include an instruction memory 510 that can store instructions that can be accessed (e.g., read) and executed by processor(s) 502. For example, the instruction memory 510 can be a non-transitory, computer-readable storage medium such as a read-only memory (ROM), an electrically erasable programmable read-only memory (EEPROM), flash memory, a removable disk, CD-ROM, any non-volatile memory, or any other suitable memory with instructions stored thereon. For example, the instruction memory 510 can store instructions that, when executed by one or more processors 502, cause one or more processors 502 to perform one or more of the operations of a differential thrust control system 200.

In addition to instruction memory 510, the computing device 500 can also include a working memory 512. Processor(s) 502 can store data to, and read data from, the working memory 512. For example, processor(s) 502 can store a working set of instructions to the working memory 512, such as instructions loaded from the instruction memory 510.

Processor(s) 502 can also use the working memory 512 to store dynamic data created during the operation of computing device 500. The working memory 512 can be a random access memory (RAM) such as a static random access memory (SRAM) or dynamic random access memory (DRAM), or any other suitable memory.

Display 514 is configured to display user interface 518. User interface 518 can enable user interaction with computing device 500. In some examples, a user can interact with user interface 518 by engaging input/output devices 506. In some examples, display 514 can be a touchscreen, where user interface 518 is displayed on the touchscreen

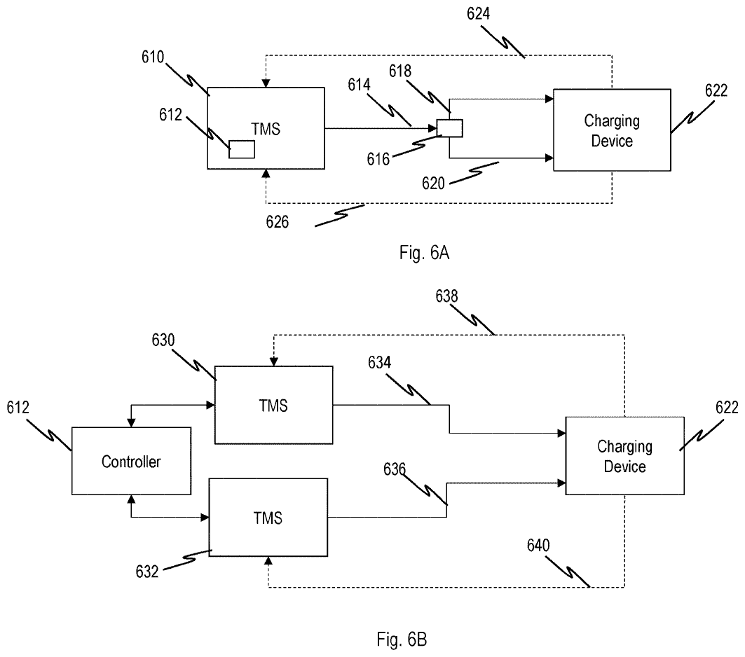

FIG. 6A depicts an arrangement implementing the thermal management system in accordance with one or more embodiments of the invention. In a non-limiting example, the TMS 610 can include the components (e.g., pump, heat exchanger, expansion tank, cooling fan, etc.) similar to that shown in the TMS 200 of FIGS. 2 and 3. The TMS 610 of FIG. 6A can include a controller 612 that is incorporated within the TMS 610. It can be appreciated that the controller 612 is similar to the controller 210 discussed with reference to FIGS. 2-4 and used to control the operation of and coolant flow through the TMS 610. The controller 612 can be coupled to and in electrical communication with each of these components. The controller 612 can be configured to receive signals from each of the components and transmit signals to control each of the components, as previously discussed with reference to FIGS. 3 and 4. As shown in FIG. 6A, a single cooling tube 614 exits the TMS 610 (coolant flows from the pump of the TMS) and is connected to a valve 616 which divides the coolant flow into the two separate paths 618, 620. In a non-limiting example, a first path 618 may be coupled to the DC+power cable and a second path 620 may be coupled to DC− power cable. The first path 618 and second path 620 of the cooling tube 614 are coupled to the DC+ and DC− power cables at the charging device 622. After the coolant flows through the charging device 622, absorbing as much of the generated heat from the DC power cables as possible, the coolant is returned to the TMS 610 to remove the absorbed heat from the coolant. The coolant is returned to the TMS 610 using a dual extraction technique where a first and second return line 624, 626 are used, instead of a single return line, to increase the cooling capacity of the TMS 610. Subsequently, the coolant is returned to the charging device 622 to continue the cycle of cooling the DC lines. The increased cooling capacity of the TMS 610 allows for fast charging of EVs to be achieved using a DC line current up to 1000 A over standard CCS cable sizes which provides an improvement over conventional systems.

FIG. 6B depicts a dual thermal management system implementing separate first and second thermal management systems 630, 632 for each DC line. In this non-limiting example, the controller 612 can be configured to control the first and the second TMS 630, 632. Similar to the arrangement shown in FIG. 6A, each TMS 630, 632 includes its own heat exchanger, expansion tank, and pump (not shown). In this arrangement, the pump, heat exchanger, expansion tank and fan are not shared between each TMS 630, 632. It can be appreciated that each TMS 630, 632 can include additional components or a different arrangement of components and is not intended to be limited by the example shown in the figures. Referring back to FIG. 6B, the DC power lines are coupled to the cooling lines within each corresponding TMS 630, 632. As shown, each DC+ and DC− line includes its own respective cooling line 634, 636 which enables the increased cooling capacity which allows for increased current/higher power to be delivered by the charging device 622. This can further decrease the charging time of an EV. For example, DC line current, using standard CCS cable size, can reach up to 1200 A when using standard GB/T cable size, the DC line current can reach up to 1400 A. Conventional charging systems are unable to reach these limits due to its inability to manage the heat generated from fast charging. When compared to the arrangement between FIGS. 6A and 6B, a further improvement can be realized in the arrangement of FIG. 6B because each DC line is provided with a dedicated TMS. Similar to the arrangement shown in FIG. 6A, after the coolant absorbs the heat from the DC lines, the coolant is returned to each respective TMS 630, 632 over respective return lines 638 and 640 to shed the absorbed heat.

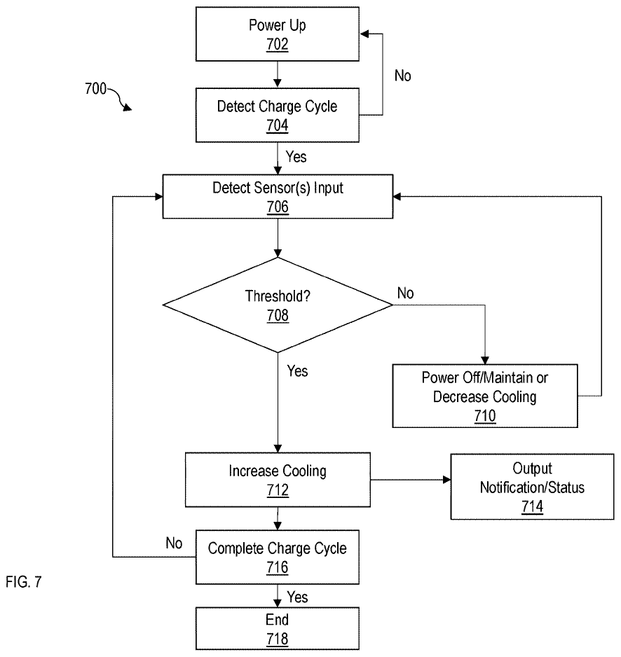

Now referring to FIG. 7, a flowchart of a method 700 for operating the TMS 200 in accordance with one or more embodiments of the invention is provided. The method 700 begins and the controller 210 can detect whether a charging device and/or charging station is powered-up at block 702. At block 704, the controller 210 can detect whether a charging device and/or charging station has entered a charging cycle to charge a load. In one or more embodiments of the invention, the controller 210 can receive a signal from the charging station indicating that the charging station is currently in a charging cycle to charge a load. If not (“no” branch), the method 700 can return to block 702 and continues to monitor whether the charging device and/or station has entered a charging cycle. If yes (“yes” branch), the method 700 continues to block 706, where the controller 210 detects one or more sensor inputs. The sensor inputs can include but are not limited to temperature and pressure inputs. The method 700 proceeds to decision block 708, where the received temperature and pressure inputs can be compared to configurable threshold values. In a scenario, if the controller 210 determines that the detected temperature from the sensor does not exceed the temperature threshold (“no” branch), the method 700 proceeds to block 710 where the controller 210 provides a control signal to the TMS to maintain its current state of operation or decrease the cooling to conserve energy.

Subsequently, the method 700 returns to block 706 to continue monitoring the sensor inputs. In a different scenario, if the controller 210 determines that the detected temperature from the sensor exceeds the temperature threshold (“yes” branch), the method 700 proceeds to block 712 where the controller 210 can provide signals to increase the cooling of the TMS. In an example, the controller 210 provides signals to the pump and/or the cooling fan to increase the cooling capacity of the system. At block 716, the controller 210 determines whether the charging cycle has been completed. If not (“no” branch), the method 700 returns to block 706 to continue to monitor the sensor inputs and continue the steps of the method 700. Otherwise (“yes” branch), the method ends at block 718. It can be appreciated that additional steps and/or a different sequence of steps can be used in other embodiments of the invention and is not limited by the examples shown in FIG. 7.

The technical effects and benefits of the embodiments of the dual extraction thermal management systems and methods described herein include improving the heat removal of a high-power, fast-charging system. The increased cooling capacity and efficiency enables fast-charging systems to operate at a higher rate without damaging the charging cables and charging devices during operation. As a result, the charging times can be drastically reduced and the charging system can be made more reliable and available for subsequent users.

The present invention may be a system, a method, and/or a computer program product at any possible technical detail level of integration. The computer program product may include a computer readable storage medium (or media) having computer readable program instructions thereon for causing a processor to carry out aspects of the present invention.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A thermal management system comprising:
a pump configured to send coolant to a charging device through a first cooling tube and a second cooling tube, wherein the first cooling tube and the second cooling tube respectively enclose a first power cable and a second power cable connected to the charging device to provide the coolant over the first power cable and the second power cable;
a heat exchanger configured to receive the coolant from the charging device from a first return tube and a second return tube; and
a controller configured to send a control signal to at least the pump to control an operation of the pump to control a flow of coolant to the charging device.

2. The thermal management system of claim 1, wherein the controller, the pump, and the heat exchanger are located within a housing.

3. The thermal management system of claim 1, further comprising a fan that is located within proximity of the heat exchanger, wherein the fan is configured to flow air over the heat exchanger to increase heat removal from the coolant flowing through the heat exchanger.

4. The thermal management system of claim 1, further comprising an expansion tank located between the charging device and the heat exchanger.

5. The thermal management system of claim 1, further comprising one or more sensors configured to detect at least one of a temperature of the coolant or a pressure within a cooling tube or return tube.

6. The thermal management system of claim 1, wherein the charging device is an electric vehicle charging device.

7. The thermal management system of claim 1, wherein the first power cable is a DC+ power cable and the second power cable is a DC− power cable.

8. A dual thermal management system comprising:
a first thermal management system coupled to a charging device, wherein the first thermal management system comprises:
a first pump configured to send coolant to the charging device through a first cooling tube, wherein the first cooling tube encloses a first power cable connected to the charging device to provide the coolant over the first power cable;
a first heat exchanger configured to receive the coolant from the charging device from a first return tube;
a second thermal management system coupled to the charging device, wherein the second thermal management system comprises:
a second pump configured to send coolant to the charging device through a second cooling tube, wherein the second cooling tube encloses a second power cable connected to the charging device to provide the coolant over the second power cable;
a second heat exchanger configured to receive the coolant from the charging device from a second return tube; and
a controller operably coupled to the first thermal management system and the second thermal management system to control the flow coolant.

9. The dual thermal management system of claim 8, wherein the first thermal management system and the second thermal management system are separate thermal management systems.

10. The dual thermal management system of claim 8, wherein the first power cable is a DC+ power cable and the second power cable is a DC− power cable.

11. The dual thermal management system of claim 8, wherein the controller can independently control operation of the first thermal management system and the second thermal management system.

12. The dual thermal management system of claim 8, wherein the first thermal management system and the second thermal management system are locating within a housing.

13. The dual thermal management system of claim 8, wherein each of the first thermal management system and the second thermal management system further comprises a fan.

14. The dual thermal management system of claim 8, wherein each of the first thermal management system and the second thermal management system further comprises a fan.

15. The dual thermal management system of claim 8, further comprising one or more sensors configured to detect at least one of a temperature of the coolant or a pressure within a cooling tube or return tube.

16. The dual thermal management system of claim 8, wherein the charging device is an electric vehicle charging device.
